(19) United States
(12) Patent Application Publication
(10) Pub. No.: US 2025/0005224 A1
(43) Pub. Date: Jan. 2, 2025

(54) PROMPT ENGINEERING FOR ARTIFICIAL INTELLIGENCE ASSISTED INDUSTRIAL AUTOMATION SYSTEM DESIGN

(71) Applicant: Rockwell Automation Technologies, Inc., Mayfield Heights, OH (US)

(72) Inventors: Michael J. Anthony, Milwaukee, WI (US); Clark L. Case, Aurora, OH (US); Michael P. D'Amico, East Troy, WI (US); Taryl J. Jasper, South Euclid, OH (US); Eryn Amara Danielle Manela, Cleveland Heights, OH (US); David C. Mazur, Mequon, WI (US); Jonathan A. Mills, Mayfield Heights, OH (US); Nathaniel S. Sandler, Cleveland, OH (US); Kurt D. Sneen, Park City, UT (US); David A. Snyder, Waukesha, WI (US)

(21) Appl. No.: 18/343,481

(22) Filed: Jun. 28, 2023

(51) Int. Cl. G06F 30/20

(52) U.S. Cl. CPC G06F 30/20

(57) ABSTRACT

Technology disclosed herein includes a prompt engineering service that integrates artificial intelligence with the programming systems of an industrial automation environment to design a system of the industrial automation environment. The interface service leverages the capabilities of a large language model (LLM) trained on industrial automation workflows to provide accurate and relevant system design information. For example, the interface service receives system configuration data and generates a first prompt requesting a category associated with the system configuration data. The interface service uses the first prompt to generate a response from the LLM. The interface service generates a second prompt requesting a user interface message for offering assistance to configure the system based on the category. The interface service uses the second prompt to generate the user interface message and displays the message in a user interface.

### RELATED APPLICATIONS

This U.S. Patent Application is related to co-pending U.S. Patent Application entitled, “PROMPT ENGINEERING FOR ARTIFICIAL INTELLIGENCE ASSISTED INDUSTRIAL AUTOMATION DEVICE CONFIGURATION,” (Docket No. 2023P-093-US) filed concurrently and co-pending U.S. Patent Application entitled, “PROMPT ENGINEERING FOR ARTIFICIAL INTELLIGENCE ASSISTED INDUSTRIAL AUTOMATION DEVICE TROUBLESHOOTING,” (Docket No. 2023P-095-US) filed concurrently, which are incorporated herein by reference in their entirety for all purposes.

### TECHNICAL FIELD

Various embodiments of the present technology relate to industrial automation environments and particularly to utilizing large language models to assist with designing systems of an industrial automation environment.

### BACKGROUND

Industrial automation systems are designed to control and optimize manufacturing processes in industries such as manufacturing, automotive, and food processing. These systems typically include networks of sensors, actuators, controllers, and software that work together to collect and analyze data. Some common types of industrial automation systems include, by way of example, Programmable Logic Controllers (PLCs), Distributed Control Systems (DCSs), Supervisory Control and Data Acquisition (SCADA) systems, etc. These systems can be designed and programmed to perform a wide range of tasks, such as monitoring and adjusting production processes, controlling the movement of materials and products, and ensuring the safety of workers and equipment.

The systems of an industrial automation environment are typically designed prior to being implemented and designing them can be challenging. For example, industrial automation systems can be incredibly complex, with many interdependent components and subsystems that need to work together seamlessly. The complexity of the system can make it difficult to predict how changes in one area of the system will impact other areas. Additionally, industrial automation systems are often made up of components from different manufacturers, each with their own proprietary protocols and communication standards. Integrating these components into a cohesive system can be a challenging task that involves a deep understanding of the hardware and software of the system, as well as the communication protocols and interfaces between the different components.

To ensure proper system design, the engineers who design the environment have technical expertise and specialized knowledge of the manufacturing processes, the required inputs and outputs, and the control algorithms that will be used to optimize production. While machine learning (ML) algorithms may be used in industrial automation environments (e.g., to adjust a device setting based on sensor data), not much progress has been made in the design and implementation of accurate and reliable ML models that facilitate designing the systems of industrial automation environments.

### SUMMARY

Technology disclosed herein includes a prompt engineering interface service that integrates artificial intelligence with the programming systems of an industrial automation environment to design one or more systems of the industrial automation environment. The prompt engineering interface service leverages the capabilities of a large language model (LLM) trained on industrial automation workflows to provide accurate and relevant system design information (e.g., proposed data models, etc.). For example, the prompt engineering interface service may generate a natural language prompt based on a user input to a system design application. The prompt may include instructions for categorizing a data model type (e.g., manufacturing system, reactors system, conveyor system, etc.), system configuration data (e.g., ladder logic, graphic representations of the system, data generated over time by components of the system, etc.), and the like. The prompt may further include instructions for generating a complete data model. The prompt engineering interface service may then transmit the prompt to an LLM or other machine learning model and receive a response based on the parameters of the prompt. The prompt engineering interface service may then incorporate the content of the response from the LLM into a user interface message for display to a user. In the same or alternative embodiment, the prompt engineering interface service modifies content of the user interface (e.g., a data model, system configuration data, etc.) and surfaces a graphical user interface (GUI) that includes the modified content.

In an implementation, a software application on a computing device directs the device to receive an input comprising system configuration data via a graphical user interface of a design application. The software application further directs the device to generate a first prompt requesting a category associated with the system configuration data and to transmit the first prompt to a large language model. The software application further directs the device to receive a first response to the first prompt from the LLM. The first response includes the category (e.g., fan, conveyor, pump, hoist, robotic assembly, control, packaging, material handling, etc.). The software application further directs the device to extract an entered data model from the design application and generate a second prompt requesting a complete data model based at least on the entered data model. The software application directs the device to transmit the second prompt to the LLM and to receive a second response to the second prompt. The second response comprises the complete data model.

This summary is provided to introduce a selection of concepts in a simplified form that are further described below in the Detailed Description. This summary is not intended to identify key features or essential features of the claimed subject matter, nor is it intended to be used as an aid in determining the scope of the claimed subject matter.

While multiple embodiments are disclosed, still other embodiments of the present technology will become apparent to those skilled in the art from the following detailed description, which shows and describes illustrative embodiments of the invention. As will be realized, the technology is capable of modifications in various aspects, all without departing from the scope of the present invention. Accordingly, the drawings and detailed description are to be regarded as illustrative in nature and not restrictive.

### BRIEF DESCRIPTION OF THE DRAWINGS

Many aspects of the disclosure can be better understood with reference to the following drawings.

FIG. 1 illustrates an exemplary operating environment in accordance with some embodiments of the present technology.

FIG. 2 illustrates a conceptual schematic environment in accordance with some embodiments of the present technology.

FIG. 3 illustrates an exemplary system design process in accordance with some embodiments of the present technology.

FIG. 4 illustrates an exemplary operational scenario in accordance with some embodiments of the present technology.

FIG. 5 illustrates an exemplary operational scenario in accordance with some embodiments of the present technology.

FIG. 6 illustrates an exemplary operational scenario in accordance with some embodiments of the present technology.

FIG. 7 illustrates an exemplary operational scenario in accordance with some embodiments of the present technology.

FIG. 8 illustrates an exemplary user interface in accordance with some embodiments of the present technology.

FIG. 9 illustrates an exemplary user interface in accordance with some embodiments of the present technology.

FIG. 10 illustrates a computing system suitable for implementing the various operational environments, architectures, processes, scenarios, and sequences discussed below with respect to the other Figures.

The drawings have not necessarily been drawn to scale. Similarly, some components or operations may not be separated into different blocks or combined into a single block for the purposes of discussion of some of the embodiments of the present technology. Moreover, while the technology is amendable to various modifications and alternative forms, specific embodiments have been shown by way of example in the drawings and are described in detail below. The intention, however, is not to limit the technology to the particular embodiments described. On the contrary, the technology is intended to cover all modifications, equivalents, and alternatives falling within the scope of the technology as defined by the appended claims. In the drawings, like reference numerals designate corresponding parts throughout the several views.

### DETAILED DESCRIPTION

Various embodiments of the present technology relate to integrating system design processes of industrial automation environments with prompt engineering techniques. Prompt engineering refers to a natural language processing concept that includes designing, developing, and refining input data (e.g., prompts) that are used to interact with artificial intelligence (AI) models, such as large language models (LLMs). The prompts are instructions that guide an AI model's behavior to produce a desired output (e.g., a complete data model). Unfortunately, it is difficult to engineer prompts for integration into the programming systems of industrial automation environments.

For example, the consequences of errors in designing industrial automation systems can be widespread and catastrophic. Existing AI models are inadequate to perform meaningful configuration activities at least because the AI models lack human intuition (e.g., the ability to make intuitive decisions based on experience or knowledge of the system, etc.), have limited understanding of system context (e.g., operating environments, regulatory requirements, safety protocols, etc.), and have data biases that are a result of the accuracy (or lack thereof) of the data upon which the AI model is trained. As such, failure of a generative AI tool to produce accurate responses for a system design process could result in safety risks, malfunctions at the device level and system wide, and significant financial losses. Additionally, concerns about data privacy and security in industrial automation environments can limit the availability of data needed for training and testing AI models. Thereby making it challenging to build accurate and reliable models that can be used in industrial settings.

To address these issues, a prompt engineering interface service is described herein that optimizes system design for industrial automation systems. The prompt engineering interface service utilizes past workflows (e.g., saved projects, etc.) of industrial automation environments to respond to user inputs with accurate and relevant system design information. The prompt engineering interface service may use a variety of techniques such as natural language processing, machine learning, and deep learning to develop accurate and effective prompts for use with large language models, chatbots, virtual assistants, and the like. For example, the prompt engineering interface service may generate natural language prompts for surfacing in a user interface (e.g., of a human-machine interface) to obtain additional context (e.g., from a user via a chat bot, from a design environment, etc.). In the same or another example, the prompt engineering interface service may generate natural language prompts to obtain relevant and accurate responses from large language models that can be incorporated into a data model, system configuration data, and the like.

In an embodiment implemented in software on one or more computing devices, an interface service receives an input and determines (e.g., based on the input) that a user is attempting to design a system of an industrial automation environment. For example, a user may submit a request to create a new data model, open an incomplete data model, interact with an incomplete data model, etc., which the interface service receives as an input. The interface service then contextualizes the input to determine if the user's request pertains to a device, a process, a system, a troubleshooting request, etc.

After determining that the user is attempting to design a system, the interface service may proceed to provide suggestions or proposals as to hardware, software, equipment, controller code, layout, timing, inputs, outputs, etc. For example, the interface service may build and/or propose an industrial automation project with specific constraints, such as a number of controllers, price point for the project, number of lines, volume of throughput, component machines, etc. The interface service may also generate control code based on receiving a description of the desired operations of the system and/or the equipment of the system (e.g., a description of a desired reactor system, cooling system, conveyor system, assembly line, etc.). In the same or another example, the interface service may generate faceplates based on a text input that describes the faceplate (e.g., with connections to the respective logic, etc.). In the same or other embodiment, the interface service may provide insights to supply chain issues and suggest alternatives that may avoid the supply chain issues (e.g., alternatives that have improved lead times, etc.).

Designing systems of an industrial automation environment can be a challenging task, owing in part to the complexity of the systems and the devices that operate in the system. Proper design ensures efficient, safe, and reliable operation of industrial automation systems. By generating prompts and leveraging the capabilities of an LLM, the system design operations described here obtain the precise design information necessary to optimize efficiency, safety, reliability, and other key performance factors for each distinctive system of an industrial automation environment. This approach ensures that each system is uniquely designed based on its specific characteristics, resulting in optimal performance and minimized downtime.

Technical advantages of the system design operations disclosed herein further include increased computational efficiency and adaptability. For example, by leveraging advanced modeling techniques, these operations require less power consumption by local computing devices, resulting in optimized resource usage. Additionally, the models associated with these operations can learn from new data and adapt their behavior over time, improving the accuracy and efficacy of designing the systems within an industrial automation environment. Furthermore, using the system design operations described herein is advantageous in that it automates the relationship linkage between the devices and their respective applications, thereby reducing processing time during application development.

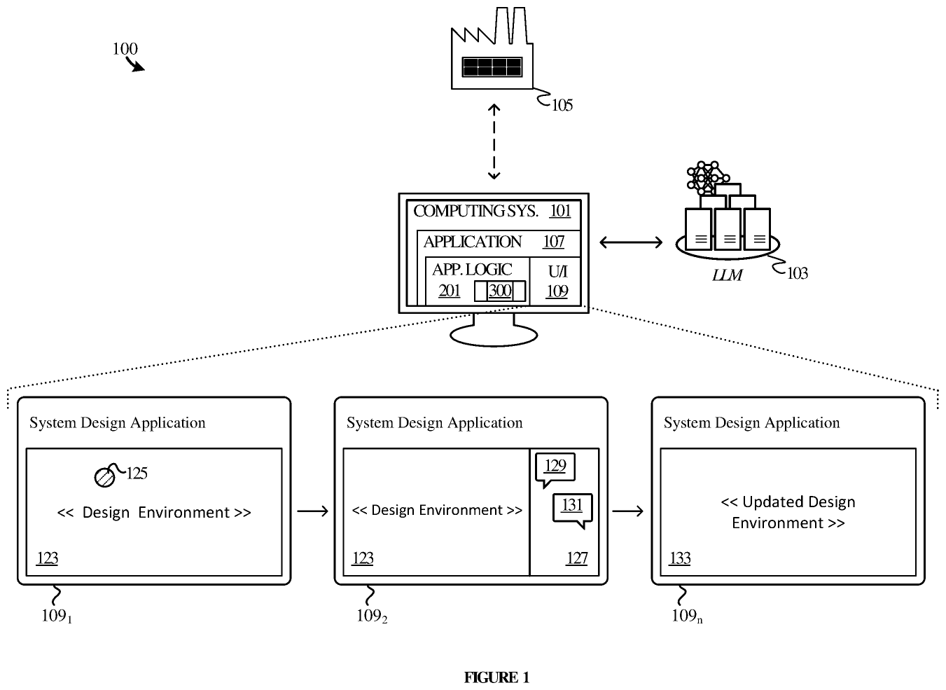

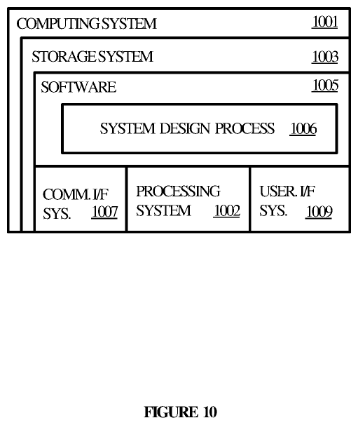

Turning now to the Figures, FIG. 1 illustrates operating environment 100 in an embodiment. Operating environment 100 includes computing system 101, model 103, and industrial automation environment 105. Computing system 101 is representative of any physical or virtual computing resource, or combination thereof, suitable for executing application 107, of which computing device 1001 of FIG. 10 is representative. Examples of computing system 101 include, but are not limited to, personal computers, laptop computers, tablet computers, mobile phones, wearable devices, external displays, virtual machines, and containers, as well as any variation, combination, or collection thereof. Computing system 101 may communicate with model 103 and/or industrial automation environment 105 via one or more network connections, examples of which include internets and intranets, the Internet, wired and wireless networks, low power wireless links, local area networks (LANs), and wide area networks (WANs). Computing system 101 includes application 107. Though computing system 101 is depicted as being separate from industrial automation environment 105, it is contemplated herein that computing system 101 may be located on the premises of industrial automation environment 105 or connected remotely thereto, for example, via a cloud-based application.

Model 103 is representative of an LLM capable of processing natural language requests to generate a desired output (e.g., a natural language response, computer code, etc.). Examples of model 103 include a Generative Pretrained Transformer (GPT) model, a Bidirectional Encoder Representations from Transformer (BERT) model, and the like. Example models include GPT-2, GPT-3, GPT-4, BLOOM, LaMDA, LLaMA, MICROSOFT TURING, and the like. Further, new models are developing that accept other modes of input including text, audio, video, images, and the like, which are referred to as large multi-mode models (LMMMs). Accordingly, model 103 may be an LLM or an LMMM. While language throughout refers to an LLM, LMMMs may be interchanged. Model 103 may be trained (e.g., via application 107) using content of an embeddings database and/or domain (not shown). An embedding database includes natural language content that is organized and accessed programmatically. The natural language content includes an embedding, which is a vector notation representative of the content as processed by a natural language model. Content of an embedding database may include system designs of saved projects, system designs of sample projects, existing validated documentation, defined bill of materials, programming manuals of devices and systems of an industrial automation system, relevant specifications of devices and systems of an industrial automation system, helpdesk articles and submissions associated with industrial automation systems, customer support tickets, etc. The embedding database may be dynamically updated by collecting analytics from a machine based on code and performance, etc. Though model 103 is depicted as being separate from industrial automation environment 105, it is contemplated herein that model 103 may be hosted on the premises of industrial automation environment 105 or hosted on a server remote to industrial automation environment 105.

Industrial automation environment 105 is representative of an industrial enterprise such as an industrial mining operation, an automobile manufacturing facility, a food processing plant, an oil drilling operation, a microprocessor fabrication facility, etc. Industrial automation environment 105 includes various machines that may be incorporated in one or more systems of industrial automation environment 105, such as drives, pumps, motors, compressors, valves, robots, and other mechanical devices. The machines, systems, and processes of industrial automation environment 105 may be located at a single location or spread out over various disparate locations.

Application 107 is representative of a system design application implemented in software and, when executed by computing system 101, renders user interface 109. Application 107 is implemented in program instructions that comprise various software modules, components, and other elements of the application. Software 1005 of FIG. 10 is representative of application 107. Application 107 may be a locally installed and executed application (e.g., of computing system 101), a desktop application, a mobile application, a streamed (or streaming) application (e.g., a cloud-based system design application accessed by computing system 101), a web-based application that is executed in the context of a web-browser, or any other type of application capable of employing application logic 201. Some commercial examples of application 107 include, but are not limited to, Rockwell Automation Studio 5000®, FactoryTalk Design Studio®, FactoryTalk Logix Echo®, and the like.

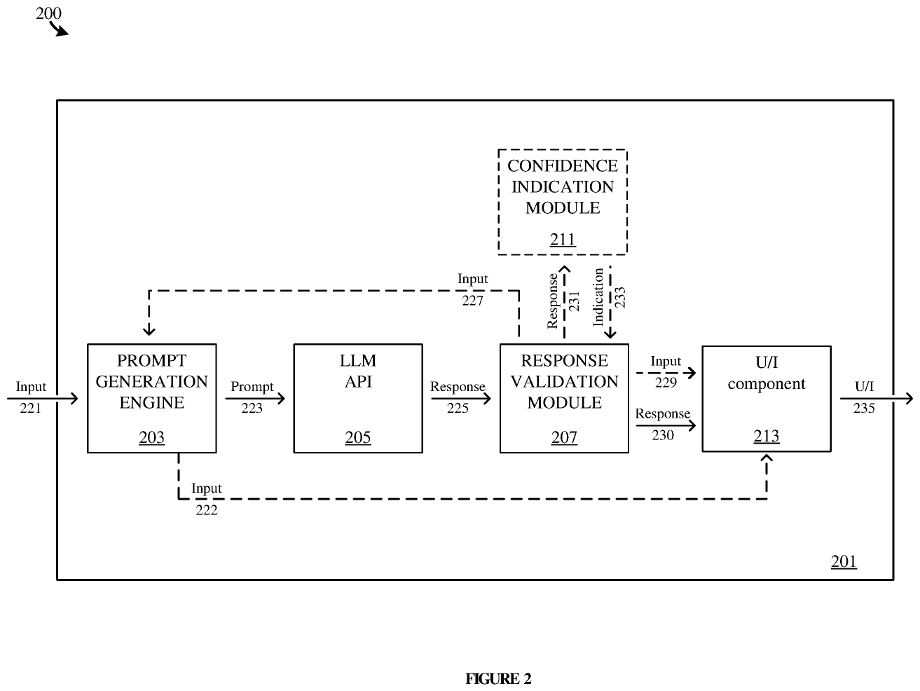

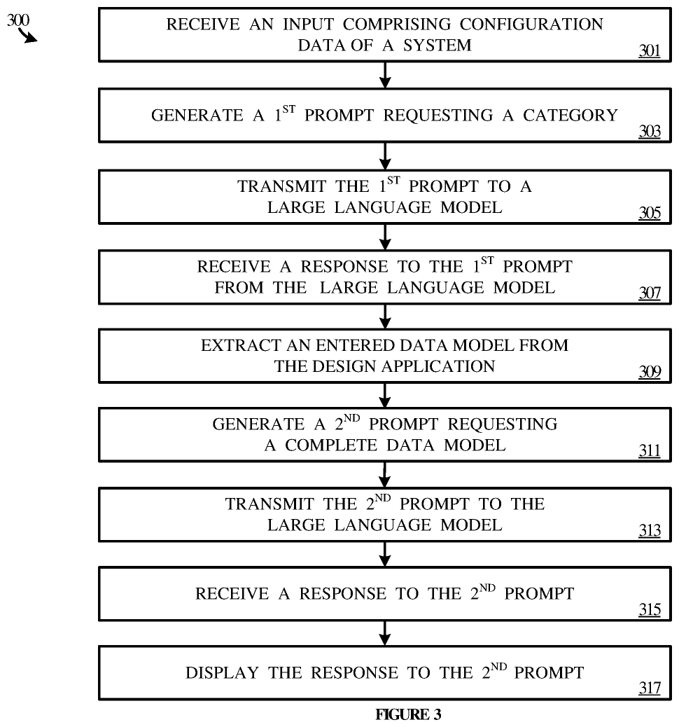

Application logic 201 (as illustrated by application logic 201 of FIG. 2) is representative of some of the functionality that may be provided by one or more of the software elements in application 107. For example, application logic 201 may be a plug-in that may be added to or otherwise accessed by application 107. Application logic 201 performs functionality such as process 300, which is described in more detail with respect to FIG. 3. Application logic 201 may be implemented in program instructions in the context of any of the software applications, modules, components, or other such elements of application 107. Application 107 employs application logic 201 to direct computing system 101 to operate as follows.

In an embodiment, computing system 101 displays, via application 107, exemplary user interfaces 109₁-109ₙ. User interface 109₁ includes an initial view of design environment 123. Design environment 123 includes an integrated system design environment in which users may design and view an industrial automation system; configure devices such as controllers, Human Machine Interfaces (HMIs), Electronic Operator Interfaces (EOIs), etc.; and manage communications between the devices. Design environment 123 may further include one or more of the following editors: ladder diagram, function block, structured text, sequential function chart, etc.

User interface 109₁ also includes user input 125. User input 125 may include creating a new data model, opening an incomplete data model, interacting with an incomplete data model, editing an existing data model, and the like. A data model of an industrial automation system includes information about the different components of the industrial automation system, such as machines, sensors, actuators, controllers, etc. that are used to monitor, control, and otherwise perform the industrial process. A data model may also include information about the different processes and workflows that are involved in the system, as well as any rules or constraints that need to be followed. Additionally, the data model may include information about the data generated by the various components of the system, including real-time sensor data, historical data, and other types of data that are used for monitoring, analysis, and optimization. This data may be stored in databases or other types of data storage systems, which may be accessed by application 107.

User input 125 may also include a drag-and-drop of a graphic representation of an industrial device (e.g., a driver of a conveyor system, a pump, a motor, a compressor, a valve, a robot, a program logic controller, etc.), an alpha-numeric query (e.g., a request for information, a request for help, a request to design a system of an industrial automation environment, etc.), a mouse click, a gesture, a voice command, etc.

Responsive to receiving user input 125 via user interface 109₁, application 107 employs application logic 201 to generate a prompt (not shown) for submission to model 103. The prompt contains a natural language query requesting system design information (e.g., a data model, etc.) based on a context of user input 125. Examples of context include history of a chat between a user and application 107, user information stored in association with a user's account, a product type, an application type, a network topology, a customer company, a power capability, available IP addresses, Azure® subscription identifiers, etc. After receiving the prompt, model 103 replies to application 107 with the system design information.

Next, computing system 101 displays, via application 107, user interface 109₂. User interface 109₂ includes the initial view of design environment 123 as well as messaging panel 127. Messaging panel 127 is representative of a chat window through which a user communicates with application 107 (e.g., via application logic 201, etc.). Messaging panel 127 may include buttons, menus, or images that can be used to provide additional information or context. Though messaging panel 127 is depicted as being a sidebar panel of user interface 109₂, it is contemplated herein that messaging panel 127 can be any user interface component capable of supporting user interactions with application 107 in a natural and conversational manner. For example, messaging panel 127 may be a popup or dialog window that overlays the content of design environment 123, and the like.

Messaging panel 127 includes messages 129 and 131. Application 107 generates message 129, which computing system 101 surfaces in user interface 109₂. For example, application 107 may generate message 129 in response to receiving user input 125, in response to receiving a reply from model 103, a combination thereof, etc. Message 129 may include a request for contextual information, a request to facilitate designing a system started in design environment 123, a request to help build a data model, and the like. Message 131 includes a user's reply to message 129. In the present embodiment, message 131 includes a positive indication for accepting the system design help offered via message 129.

In response to message 131, application 107 designs the system (not shown) and causes user interface 109ₙ to be displayed by computing system 101. User interface 109ₙ includes updated design environment 133, which includes the designed system (not shown). Application 107 may also (e.g., in response to message 131) provide lead times for the equipment noted in the system design; provide alternatives to the equipment noted in the system design; order the equipment included in the system design; configure a device, system, and/or process of industrial automation environment 105 based on the system design; etc.

FIG. 2 illustrates a conceptual schematic 200 for designing an industrial automation system in accordance with some embodiments of the present technology. Schematic 200 includes application logic 201, of which application 107 of FIG. 1 and software 1005 of FIG. 10 may be representative. Application logic 201 is implemented in program instructions that comprise various software modules, components, and other elements of the application such as engine 203, API 205, module 207, module 211, and component 213. Application logic 201 may be a locally installed and executed application, a desktop application, a mobile application, a streamed (or streaming) application, a web-based application that is executed in the context of a web-browser, or any other type of application capable of employing process 300 of FIG. 3. Though the functionality of application logic 201 is described as occurring within specific modules, it is contemplated herein that the disclosed functionality may be implemented by one or more of the software modules, components, and/or other elements of application logic 201 without departing from the scope of the disclosure.

Engine 203 is representative of a prompt generation engine that employs natural language processing and machine learning algorithms to generate natural language prompts for use with LLMs (e.g., model 103 of FIG. 1). Engine 203 includes a natural language model, a prompt database, and a prompt generator. The prompt database contains prompts that are related to fine-tuned models that were trained on task-specific data (e.g., acceptable questions and corresponding answers, speaking with a specific voice, categorization, identifying context of a user input, etc.) to learn patterns in language used in industrial automation environments and to understand the nuances of said language. The prompt generator of engine 203 uses the natural language model and prompt database to generate natural language prompts in response to user inputs (e.g., inputs 221 and 227). The prompt generator may use a variety of techniques, including rule-based systems, machine learning algorithms, and deep learning models, to generate accurate and effective prompts. Engine 203 is further configured to receive inputs 221 and 227 and to generate input 222 and prompt 223.

Engine 203 may also use a content gate that includes various rules to filter out user inputs when certain types of questions or information are encountered. For example, the content gate may, based on the various rules, prohibit answering queries that do not pertain to industrial automation systems, one of the defined categories, etc.; that are related to safety critical items or items for which human life may be in danger; etc. In such a scenario, engine 203 may generate input 222 and transmit input 222 to component 213. Input 222 may indicate that the user's inquiry cannot be answered and may instruct component 213 to either generate a user interface (e.g., requesting additional input, etc.) or cease interacting with the user (e.g., close a chat window, etc.). In the same or other embodiment, the content gate may include a rule to respond to a question that relates to a helpdesk entry by summarizing the helpdesk entry and providing additional information, to respond to a question that is unrelated to industrial automation by stating that only answers related to industrial automation can be answered, etc.

API 205 is representative of an application programming interface (API) to a large language model. Specifically, API 205 includes a set of programming instructions and standards for accessing and interacting with an LLM (e.g., model 103). API 205 is configured to receive prompt 223 from engine 203, transmit prompt 223 to the LLM, receive response 225 from the LLM, and transmit response 225 to module 207.

Module 207 is representative of a response validation module and is responsible for evaluating the quality and accuracy of responses received by API 205 from an LLM. To ensure the quality and accuracy of a response, module 207 may use a combination of rule-based systems and machine learning algorithms to validate the response and ensure that it meets certain criteria. For example, module 207 may validate a response based on factors such as the relevance of the response to a user's query (e.g., input 221), the accuracy of the information presented in the response, the naturalness and fluency of the language used in the response, etc. The response may also be validated to ensure it is free of biasing, expletives, and the like. Because LLMs are trained on enormous data sets that are not reviewed prior to training, the responses may include invalid data, erroneous data, biased data, inappropriate data, and the like. Module 207 may also incorporate feedback mechanisms that incorporate user ratings of the quality of responses as well as other feedback to improve future responses. Module 207 is further configured in some embodiments to receive response 225 from LLM API 205 and indication 233 from module 211. Module 207 is further configured in some embodiments to generate input 227 and response 231. Accordingly, in some embodiments, the LLM may validate its own response. Module 207 outputs the response 230 upon validation.

Module 211 is representative of an optional confidence indication module that provides an indication of the accuracy of the responses received from an LLM. Module 211 uses machine learning algorithms to analyze the response and generate a confidence score for each received response. The confidence score may be based on factors such as the accuracy of the language model, the relevance of the response to the user's query, and the degree of uncertainty in the data. Additionally, the confidence score can be used by application logic 201 to monitor the performance of the engine 203 with regard to the responses received by the LLM and identify areas for improvement. Module 211 is further configured to receive response 231 and to generate indication 233.

Component 213 is representative of a user interface component that presents graphical user interfaces for surfacing prompts, system configuration information, data models, etc. and enables user interactions with application logic 201. Component 213 may include a set of graphical user interface (GUI) controls such as buttons, menus, text boxes, and other interactive elements that allow users to input data and interact with the system. Component 213 may interact with other components of application logic 201, such as the business logic layer, the data access layer, and the communication layer. For example, when a user enters data into a text box, the user interface component may communicate with the business logic layer to process the data and update the underlying data model. Component 213 is further configured to receive input 222, input 229, and input 227 and to generate user interface 235.

In an embodiment, engine 203 receives input 221. Input 221 may include a request to create a new data model, opening an incomplete data model, interacting with an incomplete data model, editing an existing data model, and the like. Input 221 may also include a drag-and-drop of a graphic representation of an industrial device (e.g., a driver of a conveyor system, a pump, a motor, a compressor, a valve, a robot, a program logic controller, etc.), an alpha-numeric query (e.g., a request for information, a request for help, a request to design a system of an industrial automation environment, etc.), a mouse click, a gesture, a voice command, etc.

Based at least on a context of input 221, engine 203 generates prompt 223. Prompt 223 may include a request for and/or an instruction to categorize the type of model a user is trying to build, to generate a user interface message asking if the user would like help building the model type, to provide information about the model type, to provide a recommendation for controller code, to provide an explanation of the controller code, to review the controller code, to provide a user interface message that includes visual content (e.g., charts, graphs, etc.), to generate visual content based on controller code, etc. Example categories of model types include fan, conveyor, pump, hoist, robotic assembly, control, packaging, material handling, etc. Engine 203 then transmits prompt 223 to API 205. API 205 transmits the prompt to an LLM (e.g., model 103 of FIG. 1) and receives response 225 from the LLM. API 205 then transmits response 225 to module 207.

Module 207 validates response 225. For example, module 207 may validate response 225 by performing a semantic analysis, sentiment analysis, topic modeling process, or the like. In some embodiments, Module 207 may validate a response from the LLM using the LLM by generating a prompt including the response in the prompt for validation. In such cases, the prompt including the response may be submitted as input 227 to engine 203 for obtaining the validation. In some embodiments, module 207 may validate a response, for example against a specification, such as validating controller code, power supply requirements, communication protocols, device settings, or the like. If module 207 determines that response 225 is invalid (e.g., response 225 includes a hallucination, an unacceptable category, an incomplete data model, etc.), then module 207 may generate input 227 and transmit input 227 to engine 203. Input 227 may include context for generating a follow-up prompt for submission by API 205 to the LLM. Alternatively, module 207 may generate input 229 and transmit input 229 to component 213. Input 229 may include context for generating a GUI that includes a request for additional information, a GUI that indicates an answer to the query is “unknown,” and the like. If module 207 determines that response 225 is valid, then module 207 generates response 230 and transmits response 230 to component 213. Response 230 includes content of response 225 in some embodiments.

Prior to transmitting response 230, module 207 may alternatively generate response 231 and transmit response 231 to module 211. Response 231 includes content of response 225, which module 211 analyzes to generate indication 233. For example, module 211 may provide a confidence rating (e.g., 80% confident that the response is accurate, etc.) or a confidence score (e.g., high confidence, low confidence, etc.) based on response 231. The higher the rating and/or score, the greater confidence module 211 has in the accuracy of the response. After generating indication 233, module 211 transmits indication 233 to module 207, which incorporates indication 233 with response 230.

Component 213 receives response 230 (or input 229) from module 207 and generates user interface 235 based on response 230 (or input 229). If response 230 includes indication 233, then user interface 235 may present the content of indication 233 as a confidence level having a rating (e.g., 65% confident of the response's accuracy), having a color-coded score (e.g., a green color indicates high confidence, a red color indicates a low confidence, etc.), and the like.

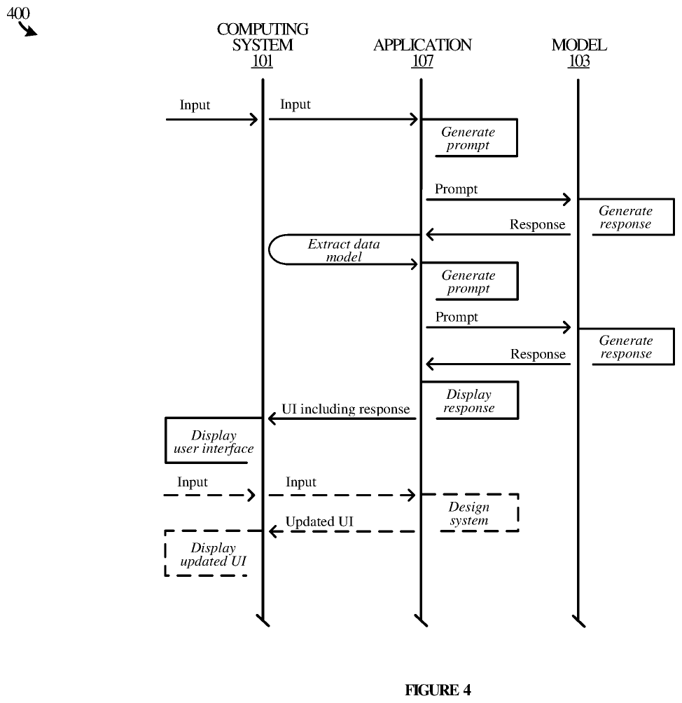

FIG. 3 illustrates a series of steps for designing a system in accordance with some embodiments of the present technology, and FIG. 4 illustrates exemplary operational scenario 400 in accordance with embodiments of the present technology. FIG. 3 includes process 300, each operation of which is noted parenthetically in the discussion below with reference to elements of FIG. 4. FIG. 4 includes computing system 101, application 107, and model 103 of FIG. 1. It may be appreciated that process 300 can be implemented in software, firmware, hardware, or any combination thereof and is representative of at least some of the functionality of application 107 of FIG. 1 and application logic 201 of FIG. 2. It may be further appreciated that process 300 is representative of system design process 1006 of FIG. 10.

In operation, application 107 receives an input comprising system configuration data, such as an entered data model (e.g., a new data model, a partial data model, etc.), ladder logic of a system, a graphic representation of the system, a description of the system design, data generated by one or more components of the system, etc. (step 301). For example, a user may interact with a GUI of application 107 to create a new data model, interact with an existing data model, etc., which application 107 receives as an input. Alternatively, the user may submit a query via an input device (e.g., keyboard, microphone, stylus, etc.) of computing system 101, which application 107 receives as an input. Application 107 may also receive the input as a mouse click of a selectable interface element, a gesture, a voice command, etc.

After receiving the input, application 107 generates a first prompt requesting a category associated with the system configuration (step 303). The first prompt may be generated in response to receiving the input. The first prompt may be generated in response to receiving, via the GUI, a second input requesting assistance to configure the system. Application 107 may generate the first prompt by providing the input to a natural language model that transforms the input into an embedding. The embedding may be included in the first prompt and used by model 103 to select relevant content from an embedding database (e.g., using natural language).

The first prompt may include aspects of the user input, such as restating all or portions of a query input, an entered data model, etc. For example, the first prompt may include context information gathered from the system configuration data and the request for a category based on the context. The first prompt may include acceptable responses such as acceptable categories of model types, product types, power capability, etc. Examples of acceptable categories may include pump, fan, hoist, conveyor, robotic assembly, control, packaging, material handling, etc. The first prompt may include a required response. For example, the first response may indicate a required response to surface if an answer to the prompt is unknown (e.g., “I'm sorry, I'm unable to answer your query,” etc.). In the same or other embodiment, the first response may indicate which phrase to include as part of a required response (e.g., “include the following at the end of your response: Do you require additional assistance,” etc.). In the same or other embodiment, the first response may indicate when to include a request for additional information in the required response (e.g., “when a category is unknown, ask the user for the unknown category, in natural language as if you were a service desk employee”).

Application 107 transmits the first prompt to model 103 (step 305). In the present embodiment, model 103 was trained via application 107 using content of an embedding database (not shown) such as saved projects, past workflows of industrial automation environments, helpdesk entries associated with the devices and systems of industrial automation environments, product catalogs associated with a plurality of devices and/or a plurality of controllers, scientific publications associated with a plurality of devices and/or a plurality of controllers, defined bills of materials, etc. Based on its training, model 103 generates a response in accordance with the instructions of the first prompt and transmits the response to application 107. Application 107 receives the response to the first prompt from model 103 (step 307), which includes the requested category. Application 107 may validate the response by using machine learning techniques to evaluate the quality and/or accuracy of the response.

Application 107 extracts an entered data model from the design application (step 309). The entered data model may be a new data model, a partial data model (e.g., an incomplete model), an existing data model, etc. The entered data model includes information about the different components of an industrial automation system (e.g., machines, sensors, actuators, controllers, etc.). The entered data model may also include information about the different processes and workflows that are involved in the system, as well as any rules or constraints that need to be followed. Additionally, the entered data model may include information about the data generated by the various components of the system, including real-time sensor data, historical data, and other types of data that are used for monitoring, analysis, and optimization.

The entered data model may also include an interaction context, such as inputs made by a user to the design environment including edits, additions, code, ladder logic, graphical representations of devices, accessing historic data associated with the entered data model, and the like. Application 107 may obtain the interaction context of the entered data model by extracting content of the entered data model from the design environment and/or a datastore, by recording or otherwise observing inputs made by the user to the design environment over time, accessing historic data associated with the entered data model, etc.

Next, application 107 generates a second prompt that includes the interaction context and an instruction requesting the LLM to provide a complete data model (step 311). The complete data model includes a detailed and accurate representation of the different components of an industrial automation system (e.g., machines, sensors, actuators, controllers, etc.). The complete data model may further include details of the data that the system manages along with the relationships between the different types of data (e.g., sensor data, operations data, etc.). In contrast, a partial data model includes a subset of the data, relationships, and/or components of the industrial automation system.

The second prompt may further include an instruction requesting the LLM to provide a message to surface in a user interface that offers assistance incorporating the complete model with the entered data model. The second prompt may also include aspects of the initial user input, the requested category, acceptable responses, required responses, etc.

Application 107 then transmits the second prompt to model 103 (step 313). Based on its training, model 103 generates a response to the second prompt and transmits the response to application 107. Application 107 receives the response to the second prompt from model 103 (step 315). The response to the second prompt includes the complete data model.

After receiving the response, application 107 generates a GUI that includes the complete data model. The GUI may also include a message offering help to design the entered data model (e.g., based on the complete data model) and requesting user input that indicates an acceptance or a refusal of the proffered help. Application 107 then transmits the GUI to computing system 101 for display by computing system 101.

Computing system 101 may receive, via the GUI, a user input that indicates an acceptance of the system design help and may transmit the input to application 107. Subsequent to receiving the input, application 107 may alter the entered data model (e.g., create a new system model, modify an existing system model, modify a draft of the system model, etc.). Application 107 may then generate an updated GUI that includes the altered system design (e.g., updated data model) and transmits the GUI to computing system 101 for display. The updated GUI may also include a message requesting user feedback on the altered system design.

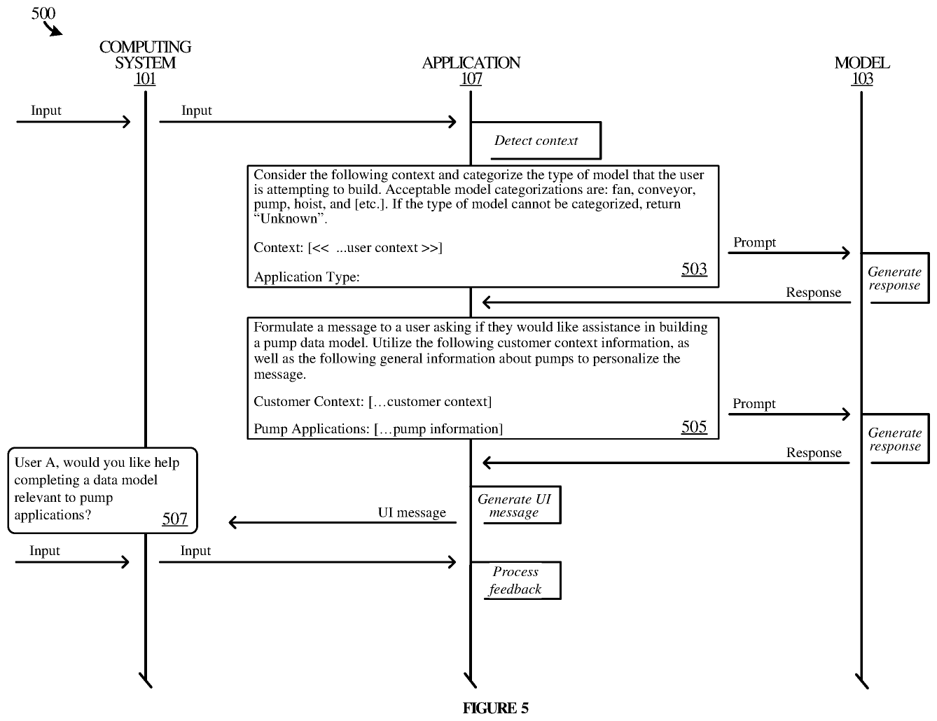

FIG. 5 illustrates exemplary operational scenario 500 in accordance with some embodiments of the present technology. The elements of operational scenario 500 include computing system 101, application 107, and model 103 of FIG. 1.

In operation, a user interacts with a GUI of application 107 via an input device (e.g., keyboard, mouse, microphone, stylus, camera, etc.) of computing system 101, which application 107 receives as an input. Example inputs include a query, a mouse click of a selectable interface element, a gesture, a voice command, a drag-and-drop of interface element, opening an existing system design project (e.g., a saved project, etc.), creating a new data model, editing an existing data model, etc. Responsive to the user input, application 107 may collect a representation of the content (e.g., a data model, etc.) being populated by the user in the GUI of application 107. In the same or other embodiment, application 107 identifies a user context which may be based on the representation, information about the user, previous interactions of the user with application 107, etc. The user context may include an initial application type, such as whether the user input relates to a system design, a data model, a device configuration, device troubleshooting, etc. In the same or other embodiment, application 107 extracts an entered data model from a design environment of application 107, the entered data model including an interaction context. The interaction context may include inputs made by a user interacting with application 107 such as edits, inputs, additions, controller code, ladder logic, etc., which may be entered via a design environment of application 107. Application 107 may use a prompt generation engine (e.g., engine 203 of FIG. 2) to identify the user context and/or the interaction context.

After identifying the user context and/or the interaction context, application 107 generates prompt 503 (e.g., via engine 203). Prompt 503 includes an instruction requesting an LLM to categorize the type of model that the user is attempting to build. Prompt 503 also includes acceptable categories of the model type (e.g., fan, conveyor, pump, hoist, etc.), and a required response if the type of model cannot be categorized (e.g., “Unknown”). Prompt 503 further includes the user context that the LLM is to analyze (e.g., “user context”). Application 107 then transmits prompt 503 to model 103.

In the present embodiment, model 103 was trained using content of an embedding database (not shown), which may include past workflows of industrial automation environments, helpdesk entries associated with the devices and systems of industrial automation environments, product catalogs associated with a plurality of devices and/or a plurality of controllers, scientific publications associated with a plurality of devices and/or a plurality of controllers, defined bill of materials, etc. Model 103 may have been trained to respond to prompt 503 by ingesting data models that differed in context, scope, application, etc. and which made up at least some of the content of the embedding database. Based on its training and the content of the embedding database, model 103 generates a response to prompt 503. The response may include the requested category and/or a required response. Model 103 then transmits the response to application 107.

Upon receiving a response to prompt 503, application 107 may validate the response (not shown). Validating the response includes determining that the response is one of the acceptable model type categories. For example, if the response includes an acceptable category, then the response may be valid, and if the response does not include an acceptable model type category, then the response may be invalid. If the response is invalid (e.g., does not include an acceptable model type category; includes an inaccurate categorization based on the configuration data, user feedback, or other analysis; etc.), application 107 may regenerate prompt 503 and transmit the regenerated prompt to model 103, repeating this action until a valid response is returned by model 103. In the same or other embodiment, an invalid response may indicate that the category is “Unknown.” A category may be unknown because the user has not entered enough items (e.g., devices, systems, processes, etc.) to the GUI of application 107 that are specific to a particular data model, etc. As the user continues to add items, application 107 may regenerate prompt 503 with the updated context of the new items and submit the updated prompt 503 to model 103. In some embodiments, application 107 may use model 103 to validate the response by generating a prompt requesting validation of the response and submitting the prompt to model 103.

Subsequent to receiving and/or validating the response, application 107 generates prompt 505 (e.g., via engine 203). Prompt 505 includes an instruction requesting an LLM to formulate a message to a user that asks whether the user would like assistance in building a data model of the category that was presented to application 107 in the response to prompt 503 (e.g., a pump application, etc.). Prompt 505 may further include the user context and information pertaining to the category that was presented to application 107 in the response to prompt 503 (e.g., generalized information about pumps, etc.). The information pertaining to the category may be retrieved by application 107 (e.g., via engine 203) from an embeddings database.

Application 107 then transmits prompt 505 to model 103, which was trained to craft personalized messages in response to prompt 505. Based on its training, model 103 generates a response to prompt 505 that includes the personalized message and transmits the response to application 107. Application 107 generates a user interface message that includes the personalized message and transmits the user interface message to computing system 101 for display by computing system 101 as user interface message 507.

Computing system 101 then receives, via the GUI, a user input that includes feedback to the personalized message. The feedback may indicate an acceptance of the system design help request, a rejection of the system design help, a correction to the category noted in user interface message 507, etc. Application 107 then processes the feedback, which may include updating the embedding database based on the feedback, regenerating prompt 503 and/or prompt 505 based on the feedback, etc.

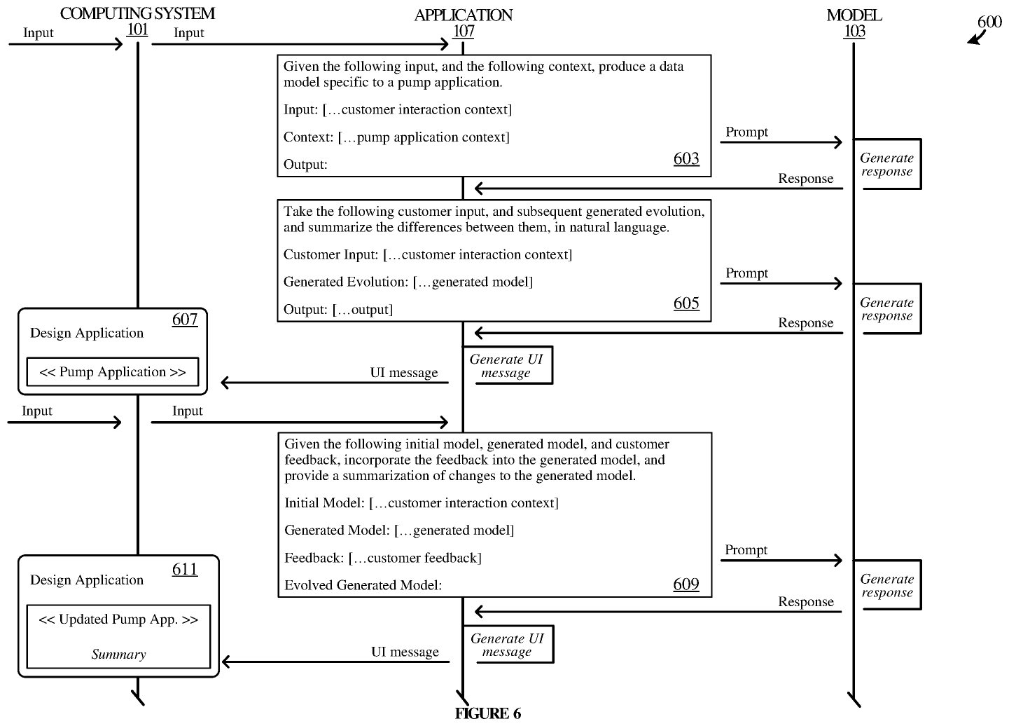

FIG. 6 illustrates exemplary operational scenario 600 in accordance with some embodiments of the present technology. The elements of operational scenario 600 include computing system 101, application 107, and model 103 of FIG. 1.

In operation, a user interacts with a GUI of application 107 via an input device (e.g., keyboard, mouse, microphone, stylus, camera, etc.) of computing system 101, which application 107 receives as an input. Example inputs include a query, a mouse click of a selectable interface element, a gesture, a voice command, a drag-and-drop of interface element, opening an existing system design project (e.g., a saved project, etc.), creating a new data model, editing an existing data model, etc. Application 107 determines, based on the input, that the user is building a data model and may need assistance. Application 107 then generates prompt 603 (e.g., via engine 203), which includes an instruction requesting the LLM to produce a data model. Prompt 603 further includes context of the data model (e.g., a pump application context, etc.). The data model context may be obtained by application 107 (e.g., via engine 203) from an embeddings database. Prompt 603 also includes a context of the user input (e.g., information about the user's systems, power capabilities of the user's systems, interactions of the user with a GUI of application 107, etc.), which may be obtained from an account database associated with the user, a company that employs or is otherwise associated with the user, etc.

Application 107 transmits prompt 603 to model 103, which was trained to ingest partial data models and output complete data. Based on its training, model 103 generates a response to the prompt 603 that includes a complete data model generated by model 103 based on the parameters of prompt 603. Model 103 then transmits the response to application 107.

Application 107 receives the response to prompt 603, which includes the complete data model. Application 107 may optionally validate the response, for example, by determining that the response includes an acceptable data model according to the system taxonomy (e.g., power capabilities of the system, etc.), application type, etc. If the response is invalid (e.g., does not include an acceptable data model, etc.), application 107 regenerates prompt 603 and transmits the regenerated prompt to model 103, repeating this action until a valid response is returned by model 103. In some embodiments, application 107 validates the response using model 103 by generating a prompt requesting validation of the response and submitting the prompt to model 103.

Subsequent to receiving and/or validating the response, application 107 generates prompt 605 (e.g., via engine 203). Prompt 605 includes an instruction to summarize the differences between the user context (e.g., the interaction context of the user with regard to the GUI of application 107, the partial data model provided by the user, etc.) and the generated data model that was provided by model 103 in the response to prompt 603. Prompt 605 further includes content of the user input and content of the generated data model. Prompt 605 may further include an example of the desired output format for the response.

Application 107 then transmits prompt 605 to model 103, which was trained to detail the differences between data models. Based on its training, model 103 generates a response to the prompt 605 that includes the generated data mode and the requested difference summary. Model 103 then transmits the response to application 107.

Application 107 generates user interface message that includes the summary detailing the differences between data models and the generated data model that was provided by model 103 in the response to prompt 605. The user interface message may also include a message requesting the user to provide feedback on the content of the user interface message. Application 107 then transmits the user interface message to computing system 101 for display by computing system 101 as message 607.

Computing system 101 receives, via the user interface message, a user input that includes feedback on the content of message 607. Application 107 then generates prompt 609, which includes an instruction for an LLM to generate an evolved data model based on the feedback and to summarize the differences between the generated model and the evolved data model. Prompt 609 further includes the user context (e.g., the initial data model), the generated data model (e.g., of the response to prompt 605), and the feedback provided by the user. Next, Application 107 transmits prompt 609 to model 103, and based on its training, model 103 generates a response to prompt 609. The response to prompt 609 includes the evolved data model and a summary of the differences between the data models. Model 103 then transmits the response to application 107.

Application 107 generates user interface message including the summary and the evolved data model provided by model 103 in the response to prompt 609. The user interface message may also include an option for the user to accept or reject the evolved data model. Application 107 then transmits the user interface message to computing system 101 for display by computing system 101 as message 611.

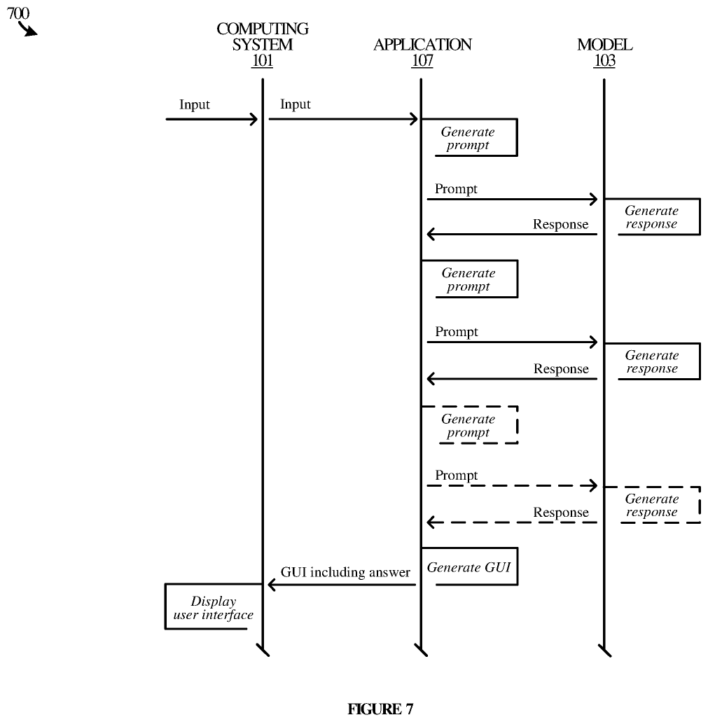

FIG. 7 illustrates exemplary operational scenario 700 in accordance with embodiments of the present technology. Operational scenario 700 includes computing system 101, application 107, and model 103 of FIG. 1.

In operation, application 107 receives a user input comprising a request for information about an industrial automation environment. For example, a user may interact with a GUI of application 107 or an input device of computing system 101 to ask for device configuration information, system configuration information, assistance with troubleshooting, assistance identifying a device, etc., which application 107 receives as an input.

After receiving the input, application 107 generates a first prompt requesting an LLM to provide a search query for use with an embedding database of the industrial automation environment. For example, application 107 may incorporate aspects of the user input into the prompt and request the LLM to provide a search query for selecting relevant content from the embedding database (e.g., using natural language). For example, application 107 may incorporate language from the request, context information, user information, etc. Context information may include information about the industrial automation environment including the current lifecycle phase, information about software being used during the request, current configuration information about the industrial automation environment, etc. User information may include a role of the user, historical information about the user, expertise of the user, etc.

Application 107 transmits the first prompt to model 103. In the present embodiment, model 103 was trained via application 107 using content of the embedding database (not shown) such as saved projects, past workflows of industrial automation environments, helpdesk entries associated with the devices and systems of industrial automation environments, product catalogs associated with a plurality of devices and/or a plurality of controllers, scientific publications associated with a plurality of devices and/or a plurality of controllers, defined bills of materials, etc. Based on its training, model 103 generates a response in accordance with the instructions of the first prompt and transmits the response to application 107. Application 107 receives the response to the first prompt from model 103, which includes the requested search query.

Application 107 then generates a second prompt that includes the search query and an instruction requesting the LLM to provide an answer responsive to the user input. The prompt may include example responses, such as details of device configurations, details of system configurations, representations of different components of an industrial automation system (e.g., machines, sensors, actuators, controllers, etc.), details of data that a system manages along with the relationships between the different types of data (e.g., sensor data, operations data, etc.), troubleshooting solutions, etc. The second prompt may also include an embedding of the user input, context information, user information, or both.

Application 107 then transmits the second prompt to model 103. Based on its training, model 103 generates a response to the second prompt and transmits the response to application 107. Application 107 receives the response to the second prompt from model 103 that includes the answer responsive to the user input.

Application 107 may optionally generate a third prompt that includes the answer responsive to the user input and an instruction requesting the LLM to validate the answer responsive to the user input. The prompt may provide validation examples that include examples of semantic analysis, sentiment analysis, a comparison to a specification, etc.

Application 107 may then transmit the third prompt to model 103. Based on its training, model 103 generates a response to the third prompt and transmits the response to application 107. Application 107 receives the response to the third prompt from model 103 that includes a validation of the answer responsive to the user input.

After receiving the response, application 107 may generate a GUI that includes the answer responsive to the user input and/or the validation. Application 107 then transmits the GUI to computing system 101 for display by computing system 101. In some embodiments, application 107 may perform further validation of the response to the third prompt before generating the GUI. For example, the response may be analyzed for bias, accuracy, length, etc.

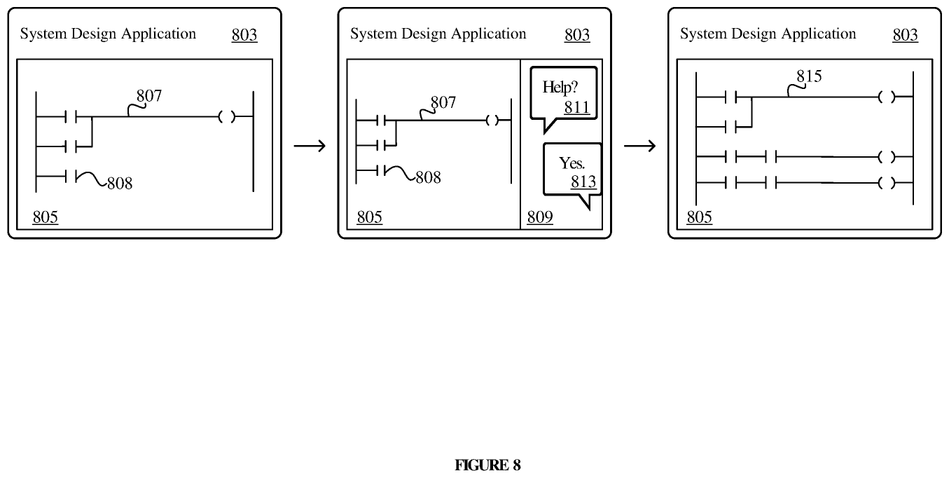

FIG. 8 illustrates an exemplary user interface 803 to a system design application (e.g., application 107 of FIG. 1) that employs a system design process (e.g., process 300 of FIG. 3) in accordance with some embodiments of the present technology. User interface 803 includes design environment 805, which initially includes ladder logic 807 of an example data model. Logic 808 is representative of a second device added to ladder logic 807, which provided additional context for the system design application to categorize the model type of ladder logic 807, which includes logic 808.

Responsive to detecting ladder logic 807, the system design application employs a system design process to generate a prompt (not shown) for submission to a LLM (not shown). The prompt contains a natural language query requesting a user interface message to surface in user interface 803 based on a context of ladder logic 807. Examples of context include an interaction context such as a representation of ladder logic 807, user context such as information stored in association with a user's account (e.g., customer information, systems data of an existing industrial automation environment, etc.), a product type, an application type, a network topology, a customer company, a power capability, available IP addresses, Azure® subscription identifiers, etc. After receiving the prompt, the LLM transmits a response to the system design application that includes the requested user interface message and a completed design for ladder logic 807.

Then, the system design application displays messaging panel 809 adjacent to design environment 805 in user interface 803. Messaging panel 809 is representative of a chat window through which a user communicates with the system design application. Messaging panel 809 may include buttons, menus, or images that can be used to provide additional information or context. Though messaging panel 809 is depicted as being a sidebar panel of user interface 803, it is contemplated herein that messaging panel 809 can be any user interface component capable of supporting user interactions with the system design application in a natural and conversational manner. For example, messaging panel 809 may be a popup or dialog window that overlays the content of design environment 805, and the like.

Messaging panel 809 includes messages 811 and 813. The system design application may generate and surface message 811, for example in response to detecting ladder logic 807, in response to receiving a response from the LLM, in response to a query submitted by the user, etc. In the present embodiment, the message 811 includes the requested user interface message that the system design application received from the LLM. Message 813 includes a user's reply to message 811, which includes a positive indication that “Yes,” the user accepts the system design proposed in message 811.

In response to message 813, the system design application updates design environment 805 to include completed data model 815. In the same or alternative embodiment, the system design application may generate a new prompt (not shown) for submission to the LLM that requests a summary describing the differences between ladder logic 807 and the completed data model 815, and may surface the summary in user interface 803 after receiving the summary from the LLM.

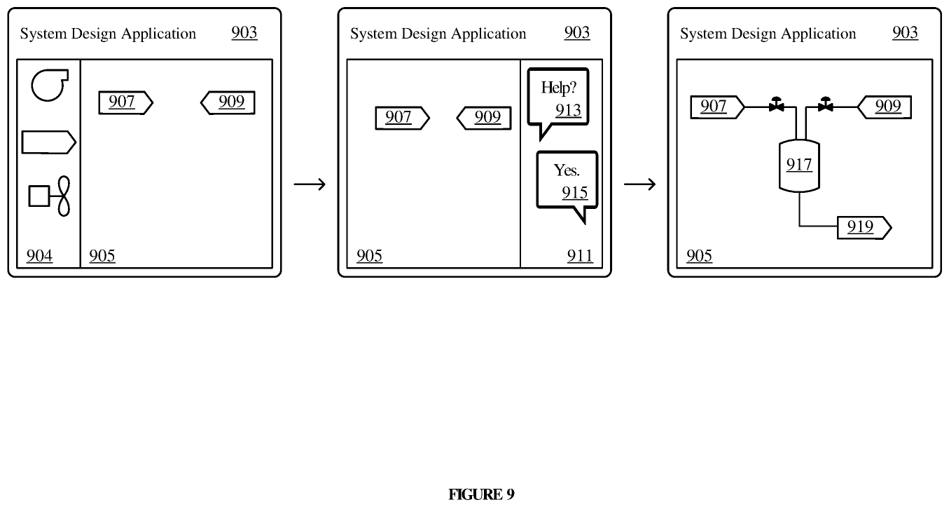

FIG. 9 illustrates an exemplary user interface 903 to a system design application (e.g., application 107 of FIG. 1) that employs a system design process (e.g., process 300 of FIG. 3) in accordance with some embodiments of the present technology. User interface 903 initially includes device menu 904 and design environment 905. Design environment 905 includes liquid feed 907 and gas feed 909, which were both added to design environment 905 as a result of a user selecting their representative icon from device menu 904.

In response to detecting liquid feed 907 and gas feed 909, the system design application employs a system design process to generate a prompt (not shown) for submission to a LLM (not shown). The prompt contains a natural language query requesting a user interface message to surface in user interface 903 based on a context of the user and/or an interaction context of the entered data model that includes liquid feed 907 and gas feed 909. Examples of context include an interaction context such as a representation of liquid feed 907 and gas feed 909, user context such as information stored in association with a user's account (e.g., customer information, systems data of an existing industrial automation environment, etc.), a product type, an application type, a network topology, a customer company, a power capability, available IP addresses, Azure® subscription identifiers, etc. After receiving the prompt, the LLM transmits a response to the system design application that includes the requested user interface message and a completed data model that includes liquid feed 907 and gas feed 909.

Then, the system design application displays messaging panel 911 adjacent to design environment 905 in user interface 903. Messaging panel 911 is representative of a chat window through which a user communicates with the system design application. Messaging panel 911 may include buttons, menus, or images that can be used to provide additional information or context. Though messaging panel 911 is depicted as being a sidebar panel of user interface 903, it is contemplated herein that messaging panel 911 can be any user interface component capable of supporting user interactions with the system design application in a natural and conversational manner. For example, messaging panel 911 may be a popup or dialog window that overlays the content of design environment 905, and the like.

Messaging panel 911 includes messages 913 and 915. The system design application may generate and surface message 913, for example, in response to detecting liquid feed 907 and/or gas feed 909, in response to receiving a response from the LLM, in response to a query submitted by the user, etc. In the present embodiment, the message 913 includes the requested user interface message that the system design application received from the LLM. Message 915 includes a user's reply to message 913, which includes a positive indication that “Yes,” the user accepts the system design proposed in message 913.

In response to message 915, the system design application updates design environment 905 to display the completed data model, which includes liquid feed 907 and gas feed 909 connected to reactor 917 which is further connected to product 919. In the same or alternative embodiment, the system design application may generate a new prompt (not shown) for submission to the LLM that requests a summary describing the differences between the entered data model (e.g., the version of the model entered by the user that included only liquid feed 907 and gas feed 909) and the completed data model (e.g., the version of the model that included liquid feed 907 and gas feed 909 connected to reactor 917 and product 919). The system design application may then surface the summary in user interface 903 after receiving the summary from the LLM.

FIG. 10 illustrates computing device 1001 that is representative of any system or collection of systems in which the various processes, programs, services, and scenarios disclosed herein may be implemented. Examples of computing device 1001 include, but are not limited to, desktop and laptop computers, tablet computers, mobile computers, and wearable devices. Examples may also include server computers, web servers, cloud computing platforms, and data center equipment, as well as any other type of physical or virtual server machine, container, and any variation or combination thereof.

Computing device 1001 may be implemented as a single apparatus, system, or device or may be implemented in a distributed manner as multiple apparatuses, systems, or devices. Computing device 1001 includes, but is not limited to, processing system 1002, storage system 1003, software 1005, communication interface system 1007, and user interface system 1009 (optional). Processing system 1002 is operatively coupled with storage system 1003, communication interface system 1007, and user interface system 1009.

Processing system 1002 loads and executes software 1005 from storage system 1003. Software 1005 includes and implements system design process 1006, which is (are) representative of the application service processes discussed with respect to the preceding Figures, such as process 300. When executed by processing system 1002, software 1005 directs processing system 1002 to operate as described herein for at least the various processes, operational scenarios, and sequences discussed in the foregoing implementations. Computing device 1001 may optionally include additional devices, features, or functionality not discussed for purposes of brevity.

Referring still to FIG. 10, processing system 1002 may comprise a micro-processor and other circuitry that retrieves and executes software 1005 from storage system 1003. Processing system 1002 may be implemented within a single processing device but may also be distributed across multiple processing devices or sub-systems that cooperate in executing program instructions. Examples of processing system 1002 include general purpose central processing units, graphical processing units, application specific processors, and logic devices, as well as any other type of processing device, combinations, or variations thereof.

Storage system 1003 may comprise any computer readable storage media readable by processing system 1002 and capable of storing software 1005. Storage system 1003 may include volatile and nonvolatile, removable and non-removable media implemented in any method or technology for storage of information, such as computer readable instructions, data structures, program modules, or other data. Examples of storage media include random access memory, read only memory, magnetic disks, optical disks, flash memory, virtual memory and non-virtual memory, magnetic cassettes, magnetic tape, magnetic disk storage or other magnetic storage devices, or any other suitable storage media. In no case is the computer readable storage media a propagated signal or a transitory signal.

In addition to computer readable storage media, in some implementations storage system 1003 may also include computer readable communication media over which at least some of software 1005 may be communicated internally or externally. Storage system 1003 may be implemented as a single storage device but may also be implemented across multiple storage devices or sub-systems co-located or distributed relative to each other. Storage system 1003 may comprise additional elements, such as a controller, capable of communicating with processing system 1002 or possibly other systems.

Software 1005 (including system design process 1006) may be implemented in program instructions and among other functions may, when executed by processing system 1002, direct processing system 1002 to operate as described with respect to the various operational scenarios, sequences, and processes illustrated herein. For example, software 1005 may include program instructions for implementing an application service process as described herein.

In particular, the program instructions may include various components or modules that cooperate or otherwise interact to carry out the various processes and operational scenarios described herein. The various components or modules may be embodied in compiled or interpreted instructions, or in some other variation or combination of instructions. The various components or modules may be executed in a synchronous or asynchronous manner, serially or in parallel, in a single threaded environment or multi-threaded, or in accordance with any other suitable execution paradigm, variation, or combination thereof. Software 1005 may include additional processes, programs, or components, such as operating system software, virtualization software, or other application software. Software 1005 may also comprise firmware or some other form of machine-readable processing instructions executable by processing system 1002.

In general, software 1005 may, when loaded into processing system 1002 and executed, transform a suitable apparatus, system, or device (of which computing device 1001 is representative) overall from a general-purpose computing system into a special-purpose computing system customized to support an application service in an optimized manner. Indeed, encoding software 1005 on storage system 1003 may transform the physical structure of storage system 1003. The specific transformation of the physical structure may depend on various factors in different implementations of this description. Examples of such factors may include, but are not limited to, the technology used to implement the storage media of storage system 1003 and whether the computer-storage media are characterized as primary or secondary storage, as well as other factors.

For example, if the computer readable storage media are implemented as semiconductor-based memory, software 1005 may transform the physical state of the semiconductor memory when the program instructions are encoded therein, such as by transforming the state of transistors, capacitors, or other discrete circuit elements constituting the semiconductor memory. A similar transformation may occur with respect to magnetic or optical media. Other transformations of physical media are possible without departing from the scope of the present description, with the foregoing examples provided only to facilitate the present discussion.

Communication interface system 1007 may include communication connections and devices that allow for communication with other computing systems (not shown) over communication networks (not shown). Examples of connections and devices that together allow for inter-system communication may include network interface cards, antennas, power amplifiers, RF circuitry, transceivers, and other communication circuitry. The connections and devices may communicate over communication media to exchange communications with other computing systems or networks of systems, such as metal, glass, air, or any other suitable communication media. The aforementioned media, connections, and devices are well known and need not be discussed at length here.

Communication between computing device 1001 and other computing systems (not shown), may occur over a communication network or networks and in accordance with various communication protocols, combinations of protocols, or variations thereof. Examples include intranets, internets, the Internet, local area networks, wide area networks, wireless networks, wired networks, virtual networks, software defined networks, data center buses and backplanes, or any other type of network, combination of network, or variation thereof. The aforementioned communication networks and protocols are well known and need not be discussed at length here.

As will be appreciated by one skilled in the art, aspects of the present invention may be embodied as a system or method and may include a computer program product, and other configurable systems. Accordingly, aspects of the present invention may take the form of an entirely hardware embodiment or an embodiment combining software (including firmware, resident software, micro-code, etc.) and hardware aspects that may all generally be referred to herein as a “circuit,” “module” or “system.” Furthermore, aspects of the present invention may take the form of a computer program product embodied in one or more computer readable medium(s) having computer readable program code embodied thereon.

Unless the context clearly requires otherwise, throughout the description and the claims, the words “comprise,” “comprising.” and the like are to be construed in an inclusive sense, as opposed to an exclusive or exhaustive sense; that is to say, in the sense of “including, but not limited to.” As used herein, the terms “connected,” “coupled,” or any variant thereof means any connection or coupling, either direct or indirect, between two or more elements; the coupling or connection between the elements can be physical, logical, or a combination thereof. Additionally, the words “herein,” “above,” “below,” and words of similar import, when used in this application, refer to this application as a whole and not to any particular portions of this application. Where the context permits, words in the above Detailed Description using the singular or plural number may also include the plural or singular number respectively. The word “or,” in reference to a list of two or more items, covers all of the following interpretations of the word: any of the items in the list, all of the items in the list, and any combination of the items in the list.

The phrases “in some embodiments,” “according to some embodiments,” “in the embodiments shown,” “in other embodiments,” and the like generally mean the particular feature, structure, or characteristic following the phrase is included in at least one implementation of the present technology, and may be included in more than one implementation. In addition, such phrases do not necessarily refer to the same embodiments or different embodiments.

The above Detailed Description of examples of the technology is not intended to be exhaustive or to limit the technology to the precise form disclosed above. While specific examples for the technology are described above for illustrative purposes, various equivalent modifications are possible within the scope of the technology, as those skilled in the relevant art will recognize. For example, while processes or blocks are presented in a given order, alternative implementations may perform routines having steps, or employ systems having blocks, in a different order, and some processes or blocks may be deleted, moved, added, subdivided, combined, and/or modified to provide alternative or subcombinations. Each of these processes or blocks may be implemented in a variety of different ways. Also, while processes or blocks are at times shown as being performed in series, these processes or blocks may instead be performed or implemented in parallel or may be performed at different times. Further any specific numbers noted herein are only examples: alternative implementations may employ differing values or ranges.

The teachings of the technology provided herein can be applied to other systems, not necessarily the system described above. The elements and acts of the various examples described above can be combined to provide further implementations of the technology. Some alternative implementations of the technology may include not only additional elements to those implementations noted above, but also may include fewer elements.

These and other changes can be made to the technology in light of the above Detailed Description. While the above description describes certain examples of the technology, and describes the best mode contemplated, no matter how detailed the above appears in text, the technology can be practiced in many ways. Details of the system may vary considerably in its specific implementation, while still being encompassed by the technology disclosed herein. As noted above, particular terminology used when describing certain features or aspects of the technology should not be taken to imply that the terminology is being redefined herein to be restricted to any specific characteristics, features, or aspects of the technology with which that terminology is associated. In general, the terms used in the following claims should not be construed to limit the technology to the specific examples disclosed in the specification, unless the above Detailed Description section explicitly defines such terms. Accordingly, the actual scope of the technology encompasses not only the disclosed examples, but also all equivalent ways of practicing or implementing the technology under the claims.

To reduce the number of claims, certain aspects of the technology are presented below in certain claim forms, but the applicant contemplates the various aspects of the technology in any number of claim forms. Any claims intended to be treated under 35 U.S.C. § 112(f) will begin with the words “means for” but use of the term “for” in any other context is not intended to invoke treatment under 35 U.S.C. § 112(f). Accordingly, the applicant reserves the right to pursue additional claims after filing this application to pursue such additional claim forms, in either this application or in a continuing application.

What is claimed is:

1. A method of operating an interface service, the method comprising:
receiving, via a graphical user interface of a design application, an input comprising configuration data of a system;
generating a first prompt requesting a category associated with the configuration data;
transmitting the first prompt to a large language model;
receiving a first response to the first prompt from the large language model, the first response comprising the category;
extracting an entered data model from the design application, wherein the entered data model comprises interaction context;
generating a second prompt requesting a complete data model, the second prompt comprising the interaction context;
transmitting the second prompt to the large language model; and
receiving a second response to the second prompt from the large language model, the second response comprising the complete data model.

2. The method of claim 1, further comprising:
validating the second response;
responsive to identifying a valid second response, displaying the second response;
responsive to identifying an invalid second response, repeating until a valid response is returned:
generating a new prompt requesting a new complete data model;
receiving a new response to the new prompt; and
validating the new response; and
responsive to identifying a valid new response, displaying the new response.

3. The method of claim 1, wherein the first prompt comprises acceptable category responses.

4. The method of claim 1, wherein the first prompt comprises a required response if the category cannot be identified.

5. The method of claim 1, further comprising editing the configuration data based on a user input selecting an element of the second response.

6. The method of claim 1, further comprising training the large language model using saved projects, customer information, prompts, and feedback as an input to the large language model.

7. The method of claim 6, wherein the large language model is trained to ingest partial data models and output complete data models.

8. The method of claim 1, further comprising detecting the input based on a user beginning a design of the system.

9. The method of claim 1, further comprising detecting the input based on a user submitting a request for assistance.

10. The method of claim 1, further comprising:
inputting the complete data model and the entered data model to a machine learning model trained to detail differences between data models;
receiving a third response comprising a difference summary; and
providing, via the graphical user interface, the difference summary, and the complete data model.

11. The method of claim 10, wherein the machine learning model is the large language model.

12. The method of claim 1, further comprising:
generating a third prompt requesting a user interface message for offering assistance to design the system based on the category;
transmitting the third prompt to a machine learning model;
receiving a third response to the third prompt;
displaying, via the graphical user interface, the third response;
receiving a positive indication, via the graphical user interface, to the third response; and
generating the second prompt in response to receiving the positive indication.

13. The method of claim 12, wherein the machine learning model is the large language model.

14. The method of claim 1, further comprising:
receiving, via the graphical user interface, feedback associated with the complete data model.

15. The method of claim 14, further comprising:
inputting the feedback associated with the complete data model, the complete data model, and the entered data model to a machine learning model trained to generate an updated model based on the input; and
receiving an updated model.

16. The method of claim 15, further comprising:
responsive to receiving new feedback associated with the updated model, repeating until no additional feedback is received:
inputting the feedback associated with the updated model, the updated model, and the complete data model to the machine learning model; and
receiving an evolved model.

17. A system, comprising:
one or more processors; and
a memory having stored thereon instructions that, upon execution by the one or more processors, cause the one or more processors to:
receive, via a graphical user interface of a design application, an input comprising configuration data of a system;
generate a first prompt requesting a category associated with the configuration data;
transmit the first prompt to a large language model;
receive a first response to the first prompt from the large language model, the first response comprising the category;
extract an entered data model from the design application, wherein the entered data model comprises interaction context;
generate a second prompt requesting a complete data model, the second prompt comprising the interaction context;
transmit the second prompt to the large language model; and
receive a second response to the second prompt from the large language model, the second response comprising the complete data model.

18. The system of claim 17, wherein the instructions further cause the one or more processors to:
validate the second response;
responsive to identifying a valid second response, display the second response;
responsive to identifying an invalid second response, repeat until a valid response is returned:
generate a new prompt requesting a new complete data model;
receive a new response to the new prompt; and
validate the new response; and
responsive to identifying a valid new response, display the new response.

19. The system of claim 17, wherein the instructions further cause the one or more processors to:
input the complete data model and the entered data model to a machine learning model trained to detail differences between data models;
receive a third response comprising a difference summary; and
provide, via the graphical user interface, the difference summary, and the complete data model.

20. A method of operating an interface service to an industrial automation environment, the method comprising:
receiving, via a graphical user interface of a design application, an input requesting information about the industrial automation environment;
generating a first prompt requesting a search query to use with an embedding database associated with the industrial automation environment;
transmitting the first prompt to a large language model;
receiving a first response to the first prompt from the large language model, the first response comprising the search query;
generating a second prompt requesting an answer to the input, the second prompt comprising the search query;
transmitting the second prompt to the large language model;
receiving a second response to the second prompt from the large language model, the second response comprising the answer;
generating a third prompt requesting a validation of the answer, the third prompt comprising the answer;
transmitting the third prompt to the large language model;
receiving a third response to the third prompt from the large language model, the third response comprising the validation; and
providing, via the graphical user interface, the answer, and the validation.
